(19) United States
(12) Patent Application Publication
(10) Pub. No.: US 2007/0018246 A1
(43) Pub. Date: Jan. 25, 2007

(54) Semiconductor device and semiconductor device manufacturing method

(75) Inventors: Juri Kato, Chino-shi (JP); Hideaki Oka, Minowa-machi (JP); Kei Kanemoto, Suwa-gun (JP); Toshiki Hara, Suwa-shi (JP); Tetsushi Sakai, Atsugi-shi (JP)

Correspondence Address: OLIFF & BERRIDGE, PLC, P.O. BOX 19928, ALEXANDRIA, VA, 22320, US

(73) Assignees: SEIKO EPSON CORPORATION, Tokyo (JP); TOKYO INSTITUTE OF TECHNOLOGY, Tokyo (JP)

(21) Appl. No.: 11/447,926

(22) Filed: Jun. 7, 2006

(30) Foreign Application Priority Data
Jul. 22, 2005 (JP) 2005-212746
Mar. 15, 2006 (JP) 2006-071328

(51) Int. Cl. H01L 27/12

(52) U.S. Cl. 257/347; 438/479

(57) ABSTRACT

A semiconductor device includes a back gate electrode composed of a first single-crystal semiconductor layer formed on a first insulating layer, a second insulating layer formed on the first single-crystal semiconductor layer, a second single-crystal semiconductor layer formed on the second insulating layer and having a film thickness smaller than a film thickness of the first single-crystal semiconductor layer, a gate electrode formed on the second single-crystal semiconductor layer, and source and drain layers that are formed on the second single-crystal semiconductor layer and arranged on respective sides of the gate electrode.

The entire disclosure of Japanese Patent Application Nos. 2005-212746 and 2006-71328, filed Jul. 22, 2005 and Mar. 15, 2006, respectively, are expressly incorporated by reference herein.

### BACKGROUND

1. Field of the Invention

The present invention relates to a semiconductor device and a semiconductor device manufacturing method and, more particularly, to ones suitable for application to a method of forming a back gate electrode of an SOI (Silicon On Insulator) transistor.

2. Description of the Related Art

A field-effect transistor formed on an SOI (Silicon On Insulator) substrate is attracting attention for its usefulness in terms of ease of element isolation, freedom from latch-up, small source/drain junction capacitances, and the like.

For example, JP-A-10-261799 discloses a method of irradiating an amorphous or polysilicon layer formed on an insulating film with ultraviolet radiation beams in a pulsed manner to form, on the insulating film, a polysilicon film having almost-cubic single-crystal grains arranged in a grid and planarize the surface of the polysilicon film by CMP (Chemical Mechanical Polishing), in order to form a silicon thin film with good crystallinity and uniformity on a large-area insulating film.

However, a silicon thin film formed on an insulating film has grain boundaries, microtwins, and various other microdefects. For this reason, a field-effect transistor formed on such a silicon thin film is inferior in transistor characteristics to a field-effect transistor formed in complete single-crystal silicon.

Also, when field-effect transistors formed on respective silicon thin films are to be stacked, a field-effect transistor is present in a lower layer. Accordingly, the planarity of an underlying insulating film on which a silicon thin film of an upper layer is formed deteriorates, and restrictions are imposed on, e.g., annealing conditions at the time of forming the silicon thin film of the upper layer. As a result, the crystallinity of the silicon thin film of the upper layer is inferior to that of the silicon thin film of the lower layer.

Additionally, in a conventional semiconductor integrated circuit, as the channel length of a transistor decreases along with its miniaturization, the rising characteristics of a drain current in a subthreshold region deteriorate. This interferes with low-voltage operation of the transistor and increases an off-leak current. Such an off-leak current not only increases the power consumed during operation or standby but also may constitute a major factor in a breakdown of the transistor.

### SUMMARY

Under the circumstances, the present invention has as its object to provide a semiconductor device and a semiconductor device manufacturing method which allow arrangement of a back gate electrode with decreased resistance under a semiconductor layer in which a field-effect transistor is formed while suppressing a deterioration in the crystallinity of the semiconductor layer, in which the field-effect transistor is formed.

In order to solve the above-described problems, a semiconductor device according to one aspect of the present invention comprises a back gate electrode composed of a first single-crystal semiconductor layer formed on a first insulating layer, a second insulating layer formed on the first single-crystal semiconductor layer, a second single-crystal semiconductor layer formed on the second insulating layer and having a film thickness smaller than a film thickness of the first single-crystal semiconductor layer, a gate electrode formed on the second single-crystal semiconductor layer, and source and drain layers that are formed on the second single-crystal semiconductor layer and arranged on respective sides of the gate electrode.

This configuration makes it possible to increase flexibility in the arrangement of a back gate electrode and arrange a back gate electrode without being limited by the arrangement of a gate electrode, source and drain contacts, and the like. Accordingly, it becomes possible to increase flexibility in the design of a field-effect transistor and control the threshold voltage of the field-effect transistor with a back gate bias or improve its subthreshold characteristics with a double gate structure.

Arrangement of a back gate electrode on the back side of a single-crystal semiconductor layer makes it possible to shield a drain potential using the back gate electrode. Accordingly, even if a drain potential is applied from the surface of a Si thin film of an SOI, a high voltage can be prevented from being applied to the interface between a drain offset layer or high-concentration impurity diffusion layer and a buried oxide film. As a result, a locally high electric field can be prevented from being produced at the interface between the drain offset layer or high-concentration impurity diffusion layer and the buried oxide film, and an increase in the breakdown voltage of an SOI transistor can be ensured.

It becomes possible to control the potential of an active region of an SOI transistor with a back gate electrode, thus allowing control of the threshold value of the SOI transistor and an improvement in the rising characteristics of a drain current in a subthreshold region. In addition, an electric field at a channel end on the drain side can be lessened. Accordingly, it becomes possible to decrease an off-leak current while allowing low-voltage operation of the transistor. This makes it possible to decrease the power consumed during operation or standby and increase the breakdown voltage of the SOI transistor.

A decrease in the resistance of the back gate electrode can be ensured by making the film thickness of the first single-crystal semiconductor layer, in which the back gate electrode is formed, larger than the film thickness of the second single-crystal semiconductor layer, in which an SOI transistor is formed. Accordingly, it becomes possible to control the threshold value of the SOI transistor at a low voltage and increase the area of the back gate electrode. This makes it possible to decrease the number of contacts connected to the back gate electrode and suppress an increase in chip size.

The semiconductor device according to the one aspect of the present invention further comprises a wiring layer that electrically connects the back gate electrode and the gate electrode.

This configuration makes it possible to control the back gate electrode and gate electrode such that they are at the same potential and increase control over the potential of a channel region. Accordingly, an off-leak current can be decreased while suppressing an increase in chip size. This makes it possible to decrease power consumed during operation or standby and ensure an increase in the breakdown voltage of a field-effect transistor.

A semiconductor device manufacturing method according to one aspect of the present invention comprises a step of forming a first single-crystal semiconductor layer on a single-crystal semiconductor substrate, a step of forming a second single-crystal semiconductor layer whose etching rate is lower than an etching rate of the first single-crystal semiconductor layer on the first single-crystal semiconductor layer, a step of forming a third single-crystal semiconductor layer having the same composition as composition of the first single-crystal semiconductor layer on the second single-crystal semiconductor layer, a step of forming a fourth single-crystal semiconductor layer having the same composition as composition of the second single-crystal semiconductor layer and a film thickness smaller than a film thickness of the second single-crystal semiconductor layer on the third single-crystal semiconductor layer, a step of forming a first trench extending through the first to fourth single-crystal semiconductor layers to expose the single-crystal semiconductor substrate, a step of forming, in the first trench, a support supporting the second and fourth single-crystal semiconductor layers on the single-crystal semiconductor substrate, a step of forming a second trench that exposes at least part of the first and third single-crystal semiconductor layers from the second and fourth single-crystal semiconductor layers supported by the support formed in the first trench, a step of selectively etching the first and third single-crystal semiconductor layers through the second trench to form first and second cavity portions obtained by removing the first and third single-crystal semiconductor layers, a step of thermally oxidizing the semiconductor substrate and the second and fourth single-crystal semiconductor layers to form respective buried oxide films that fill in the first and second cavity portions, a step of thermally oxidizing the fourth single-crystal semiconductor layer to form a gate insulating film on the fourth single-crystal semiconductor layer, a step of forming a gate electrode on the fourth single-crystal semiconductor layer through the gate insulating film, and a step of performing ion implantation using the gate electrode as a mask to form source and drain layers arranged on respective sides of the gate electrode on the fourth single-crystal semiconductor layer.

This configuration makes it possible to bring an etchant into contact with the first and third single-crystal semiconductor layers through the second trench even if the second and fourth single-crystal semiconductor layers are stacked on the first and third single-crystal semiconductor layers, respectively. It becomes possible to remove the first and third single-crystal semiconductor layers while leaving the second and fourth single-crystal semiconductor layers intact and form respective buried oxide films that fill in the first and second cavity portions under the second and fourth single-crystal semiconductor layers. Formation of the support that fills in the first trench makes it possible to support the second and fourth single-crystal semiconductor layers on the single-crystal semiconductor substrate even if the first and second cavity portions are formed under the second and fourth single-crystal semiconductor layers, respectively. The film thickness of the fourth single-crystal semiconductor layer larger than that of the second single-crystal semiconductor layer makes it possible to stably support the fourth single-crystal semiconductor layer.

For this reason, it becomes possible to arrange the second and fourth single-crystal semiconductor layers on the buried oxide films while decreasing the occurrence of defects in the second and fourth single-crystal semiconductor layers. It becomes possible to arrange a back gate electrode with decreased resistance on the back side of the second single-crystal semiconductor layer without using an SOI substrate and form an SOI transistor in the second single-crystal semiconductor layer. As a result, it becomes possible to decrease an off-leak current of the SOI transistor while suppressing an increase in cost and ensure an increase in the breakdown voltage of the SOI transistor.

In the semiconductor device manufacturing method according to the one aspect of the present invention, the single-crystal semiconductor substrate and the second and fourth single-crystal semiconductor layers are made of Si, and the first and third single-crystal semiconductor layers are made of SiGe.

This configuration makes it possible to make etching rates of the first and third single-crystal semiconductor layers higher than those of the single-crystal semiconductor substrate and the second and fourth single-crystal semiconductor layers while lattice matching the single-crystal semiconductor substrate and the first to fourth single-crystal semiconductor layers to each other. Accordingly, it becomes possible to form the second and fourth single-crystal semiconductor layers with good crystalline quality on the first and third single-crystal semiconductor layers, respectively, and ensure insulation between the second and fourth single-crystal semiconductor layers and the single-crystal semiconductor substrate without impairing the qualities of the second and fourth single-crystal semiconductor layers.

The semiconductor device manufacturing method according to the one aspect of the present invention comprises a step of ion-implanting, into the second single-crystal semiconductor layer, an impurity whose range is set to be longer than a depth of a center in a direction of film thickness of the second single-crystal semiconductor layer.

This method makes it possible to ensure a decrease in the resistance of a back gate electrode while suppressing damage to the fourth single-crystal semiconductor layer, in which an SOI transistor is formed, and control the threshold value of the SOI transistor at a low voltage over a long distance without deteriorating the characteristics of the SOI transistor.

### BRIEF DESCRIPTION OF THE DRAWINGS

FIG. 1 is a section view showing the schematic configuration of a semiconductor device according to a first embodiment of the present invention;

FIGS. 2A to 2C are views showing a semiconductor device manufacturing method according to a second embodiment of the present invention;

FIGS. 3A to 3C are views showing the semiconductor device manufacturing method according to the second embodiment of the present invention;

FIGS. 4A to 4C are views showing the semiconductor device manufacturing method according to the second embodiment of the present invention;

FIGS. 5A to 5C are views showing the semiconductor device manufacturing method according to the second embodiment of the present invention;

FIGS. 6A to 6C are views showing the semiconductor device manufacturing method according to the second embodiment of the present invention;

FIGS. 7A to 7C are views showing the semiconductor device manufacturing method according to the second embodiment of the present invention;

FIGS. 8A to 8C are views showing the semiconductor device manufacturing method according to the second embodiment of the present invention;

FIGS. 9A to 9C are views showing the semiconductor device manufacturing method according to the second embodiment of the present invention;

FIGS. 10A to 10C are views showing the semiconductor device manufacturing method according to the second embodiment of the present invention;

FIGS. 11A to 11C are views showing the semiconductor device manufacturing method according to the second embodiment of the present invention; and

FIGS. 12A to 12C are views showing the semiconductor device manufacturing method according to the second embodiment of the present invention.

### DETAILED DESCRIPTION OF THE PREFERRED EMBODIMENTS

A semiconductor device and its manufacturing method according to embodiments of the present invention will be explained below with reference to the drawings.

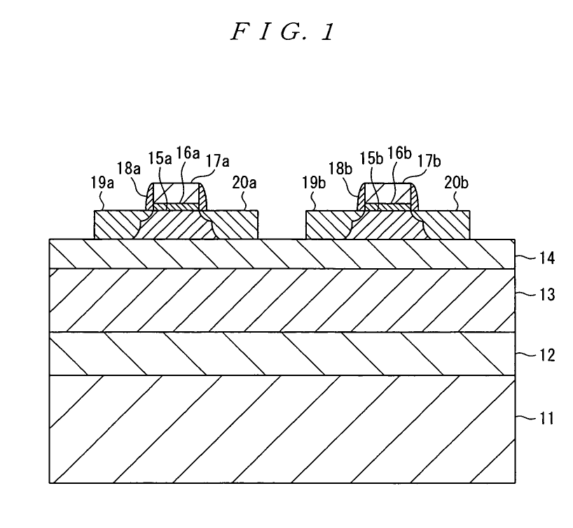

FIG. 1 is a section view showing the schematic configuration of a semiconductor device according to a first embodiment of the present invention.

In FIG. 1, a buried oxide film 12 is formed on a single-crystal semiconductor substrate 11, and a first single-crystal semiconductor layer 13 constituting back gate electrodes is formed on the buried oxide film 12. A buried oxide film 14 is formed on the first single-crystal semiconductor layer 13, and mesa-isolated second single-crystal semiconductor layers 15a and 15b are stacked on the buried oxide film 14. Note that Si can be used as a material for the single-crystal semiconductor substrate 11, first single-crystal semiconductor layer 13, and second single-crystal semiconductor layers 15a and 15b. The film thicknesses of the second single-crystal semiconductor layers 15a and 15b are preferably larger than that of the first single-crystal semiconductor layer 13.

A gate electrode 17a is formed on the second single-crystal semiconductor layer 15a through a gate insulating film 16a, and sidewalls 18a are formed on side walls of the gate electrode 17a. A source layer 19a and a drain layer 20a which are arranged such that the gate electrode 17a is sandwiched between them are also formed on the second single-crystal semiconductor layer 15a. A gate electrode 17b is formed on the second single-crystal semiconductor layer 15b through a gate insulating film 16b, and sidewalls 18b are formed on side walls of the gate electrode 17b. A source layer 19b and a drain layer 20b which are arranged such that the gate electrode 17b is sandwiched between them are also formed on the second single-crystal semiconductor layer 15b.

This configuration makes it possible to form respective SOI transistors in the second single-crystal semiconductor layers 15a and 15b and arrange a back gate electrode on the back side of each SOI transistor. Accordingly, it becomes possible to increase flexibility in the arrangement of the back gate electrodes and arrange the back gate electrodes without being limited by the arrangement of the gate electrodes 17a and 17b, source and drain contacts, and the like.

For this reason, it becomes possible to increase flexibility in the design of the SOI transistors and control the threshold voltage of each SOI transistor with a back gate bias or improve its subthreshold characteristics with a double gate structure.

The arrangement of the back gate electrodes on the back sides of the second single-crystal semiconductor layers 15a and 15b makes it possible to shield drain potentials using the back gate electrodes. Accordingly, even if a drain potential is applied from the surface of the Si thin film of each SOI, a high voltage can be prevented from being applied to the interface between the corresponding one of the drain layers 20a and 20b and the buried oxide film 14. As a result, a locally high electric field can be prevented from being produced at the interface between each of the drain layers 20a and 20b and the buried oxide film 14, and an increase in the breakdown voltage of each SOI transistor can be ensured.

It becomes possible to control the potential of an active region of each SOI transistor with the corresponding back gate electrode, thus allowing control of the threshold value of the SOI transistor and an improvement in the rising characteristics of a drain current in a subthreshold region. In addition, electric fields at channel ends on the drain layers 20a and 20b sides can be lessened. Accordingly, it becomes possible to decrease an off-leak current while allowing low-voltage operation of the SOI transistor. This makes it possible to decrease the power consumed during operation or standby and increase the breakdown voltage of the SOI transistor.

A decrease in the resistance of each back gate electrode can be ensured by making the film thickness of the first single-crystal semiconductor layer 13, in which the back gate electrodes are formed, larger than that of the second single-crystal semiconductor layers 15a and 15b, in which the SOI transistors are formed. Accordingly, it becomes possible to control the threshold value of each SOI transistor at a low voltage and increase the area of each back gate electrode. This makes it possible to decrease the number of contacts connected to the back gate electrodes and suppress an increase in chip size.

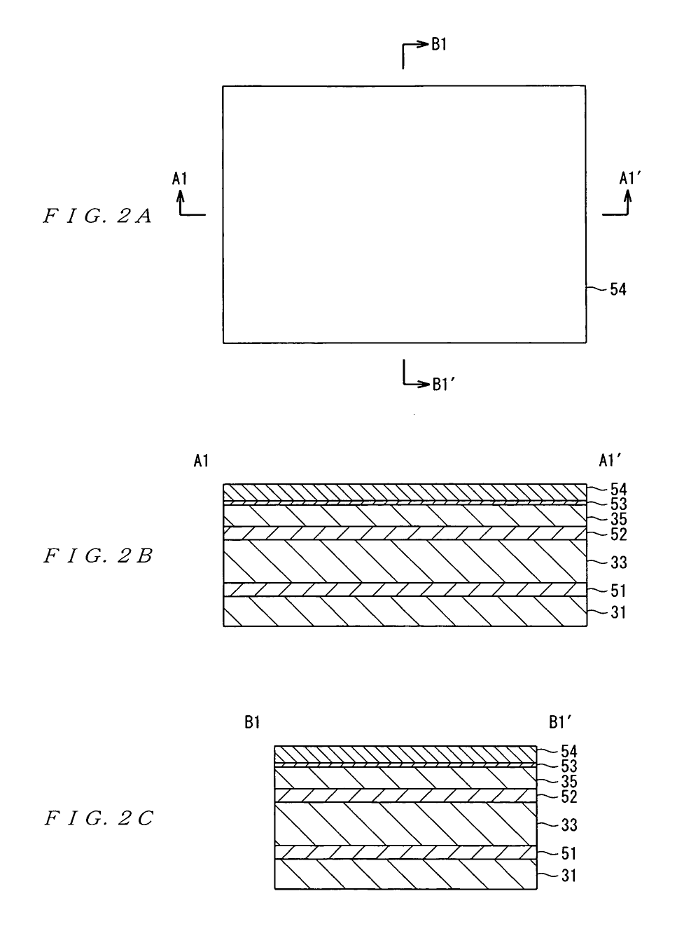

FIGS. 2A to 12A are plan views showing a semiconductor device manufacturing method according to a second embodiment of the present invention; FIGS. 2B to 12B, section views taken along the lines A1-A1′ to A11-A11′ in FIGS. 2A to 12A, respectively; and FIGS. 2C to 12C, section views taken along the lines B1-B1′ to B11-B11′ in FIGS. 2A to 12A, respectively.

In FIGS. 2A to 2C, single-crystal semiconductor layers 51, 33, 52, and 35 are sequentially stacked on a single-crystal semiconductor substrate 31 by epitaxial growth. At this time, the film thickness of the single-crystal semiconductor layer 33 can be made larger than that of the single-crystal semiconductor layer 35. As materials for the single-crystal semiconductor layers 51 and 52, ones whose etching rates are higher than those of the single-crystal semiconductor substrate 31 and single-crystal semiconductor layers 33 and 35 can be used. In particular, if the single-crystal semiconductor substrate 31 is made of Si, it is preferable to use SiGe as a material for the single-crystal semiconductor layers 51 and 52 and Si as a material for the single-crystal semiconductor layers 33 and 35. This makes it possible to lattice match the single-crystal semiconductor layers 51 and 52 and the single-crystal semiconductor layers 33 and 35 to each other and ensure a certain level of selectivity between the single-crystal semiconductor layers 51 and 52 and the single-crystal semiconductor layers 33 and 35. The film thicknesses of the single-crystal semiconductor layers 51, 33, 52, and 35 can be set to, e.g., about 1 to 100 nm.

A sacrificial oxide film 53 is formed on the surface of the single-crystal semiconductor layer 35 by thermally oxidizing the single-crystal semiconductor layer 35. An oxidation-resistant film 54 is formed all over the sacrificial oxide film 53 by CVD or the like. Note that, for example, a silicon nitride film can be used as the oxidation-resistant film 54.

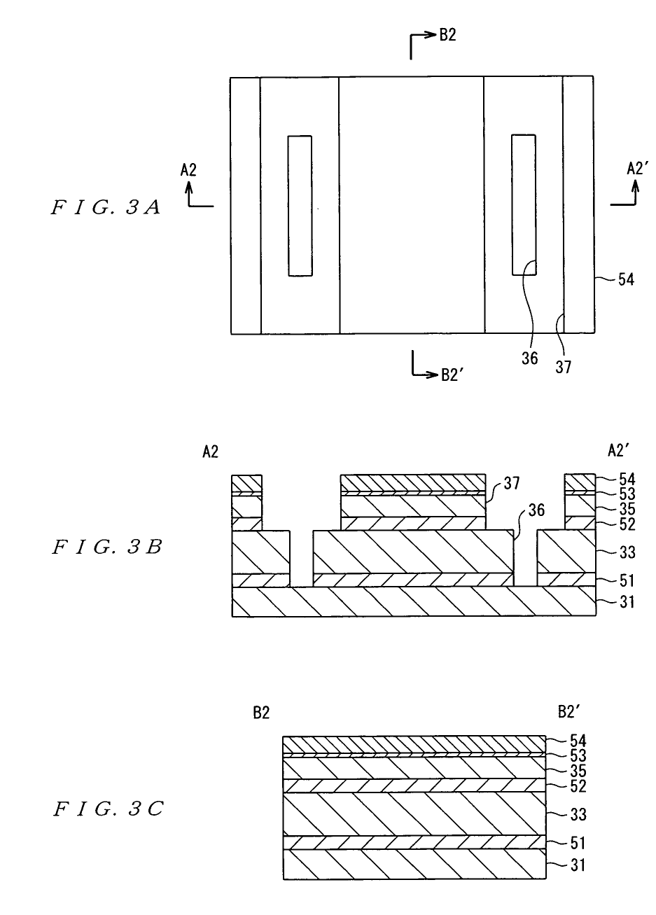

As shown in FIGS. 3A to 3C, the oxidation-resistant film 54, sacrificial oxide film 53, single-crystal semiconductor layers 35, 52, 33, and 51 are patterned using a photolithography technique and etching technique, thereby forming trenches 36 which expose the single-crystal semiconductor substrate 31 in a predetermined direction. To expose the single-crystal semiconductor substrate 31, etching may be stopped at the surface of the single-crystal semiconductor substrate 31 or the single-crystal semiconductor substrate 31 may be overetched to form recessed portions therein. The position where each trench 36 is located can be made to correspond to part of an element isolation region of the single-crystal semiconductor layer 33.

The oxidation-resistant film 54, sacrificial oxide film 53, single-crystal semiconductor layers 35 and 52 are further patterned using a photolithography technique and etching technique, thereby forming trenches 37, each of which is located so as to overlap a corresponding one of the trenches 36 and wider than the trench 36. The position where each trench 37 is located can be made to correspond to an element isolation region of the semiconductor layer 35.

Instead of exposing the surface of the single-crystal semiconductor layer 33, etching maybe stopped at the surface of the single-crystal semiconductor layer 52 or the single-crystal semiconductor layer 52 may be overetched such that it is etched halfway through its thickness. Stopping etching halfway through the single-crystal semiconductor layer 52 makes it possible to prevent the surface of the single-crystal semiconductor layer 33 in the trench 36 from being exposed. Accordingly, it becomes possible to decrease the time over which the single-crystal semiconductor layer 33 in the trench 36 is exposed to an etchant or etching gas when etching and removing the single-crystal semiconductor layers 51 and 52 and suppress overetching of the single-crystal semiconductor layer 33 in the trench 36.

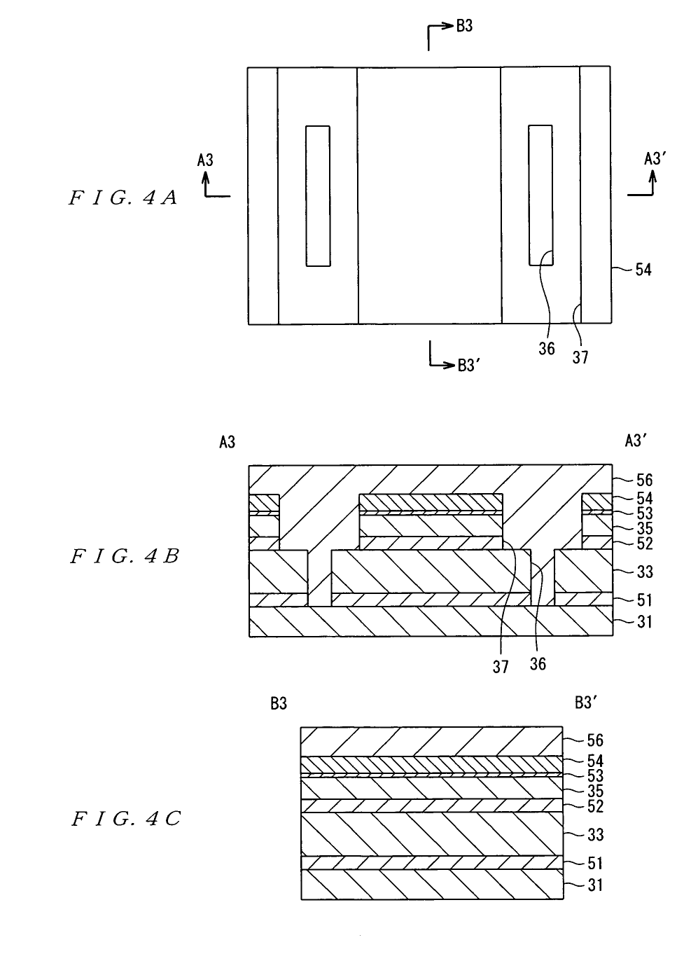

As shown in FIGS. 4A to 4C, a support 56 which fills in the trenches 36 and 37 and supports the single-crystal semiconductor layers 33 and 35 on the single-crystal semiconductor substrate 31 is formed all over the single-crystal semiconductor substrate 31 by CVD or the like. Note that a silicon oxide film can be used as a material for the support 56.

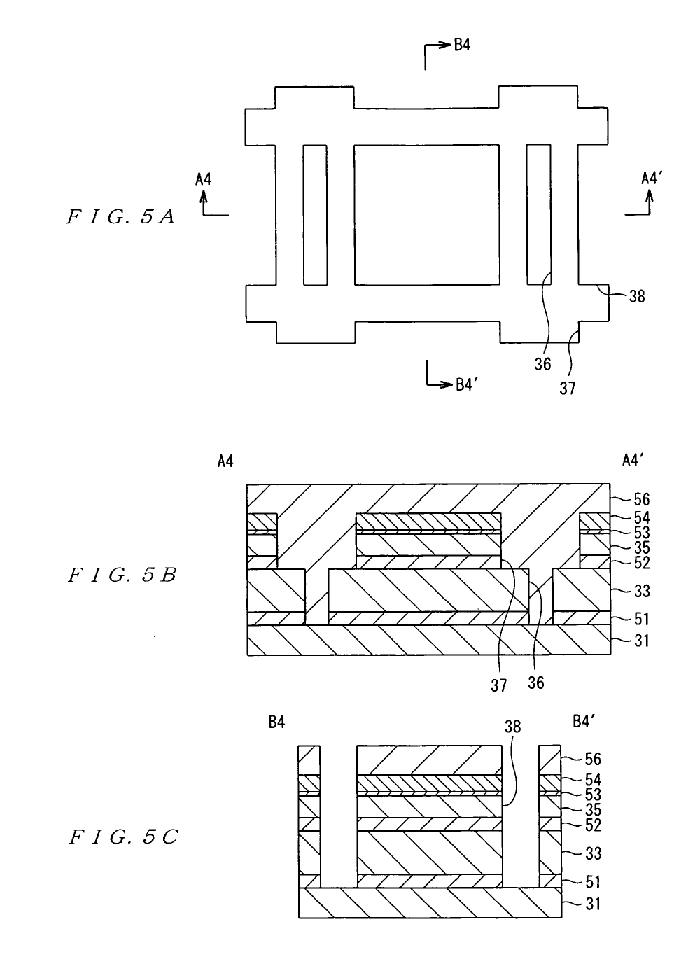

As shown in FIGS. 5A to 5C, the oxidation-resistant film 54, sacrificial oxide film 53, single-crystal semiconductor layers 35, 52, 33, and 51 are patterned using a photolithography technique and etching technique, thereby forming trenches 38 which expose the single-crystal semiconductor substrate 31 in a direction orthogonal to the trenches 36. To expose the single-crystal semiconductor substrate 31, etching may be stopped at the surface of the single-crystal semiconductor substrate 31 or the single-crystal semiconductor substrate 31 may be overetched to form recessed portions therein. The position where each trench 38 is located can be made to correspond to element isolation regions of the single-crystal semiconductor layers 33 and 35.

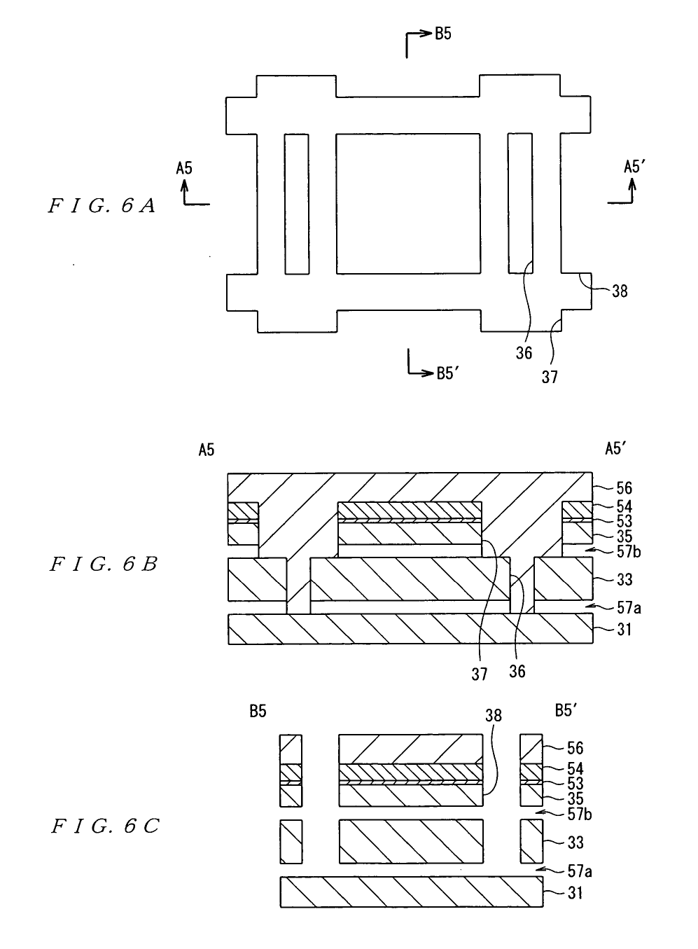

As shown in FIGS. 6A to 6C, the single-crystal semiconductor layers 51 and 52 are etched and removed by bringing an etchant into contact with the single-crystal semiconductor layers 51 and 52 through the trenches 38. Cavities 57a are formed between the single-crystal semiconductor substrate 31 and the single-crystal semiconductor layer 33, and cavities 57b are formed between the single-crystal semiconductor layers 33 and 35.

The support 56 in the trenches 36 and 37 makes it possible to support the single-crystal semiconductor layers 33 and 35 on the single-crystal semiconductor substrate 31 even if the single-crystal semiconductor layers 51 and 52 are removed. Also, the trenches 38 formed separately from the trenches 36 and 37 makes it possible to bring an etchant into contact with the single-crystal semiconductor layers 51 and 52 arranged under the single-crystal semiconductor layers 33 and 35, respectively. Accordingly, insulation between the single-crystal semiconductor layers 33 and 35 and the single-crystal semiconductor substrate 31 can be ensured without impairing the crystalline qualities of the single-crystal semiconductor layers 33 and 35.

Note that if the single-crystal semiconductor substrate 31 and single-crystal semiconductor layers 33 and 35 are made of Si, and the single-crystal semiconductor layers 51 and 52 are made of SiGe, hydrofluoric-nitric acid is preferably used as an etchant for the single-crystal semiconductor layers 51 and 52. This makes it possible to obtain a selectivity of about 1:100 to 1:1000 as one between Si and SiGe and remove the single-crystal semiconductor layers 51 and 52 while suppressing overetching of the single-crystal semiconductor substrate 31 and single-crystal semiconductor layers 33 and 35.

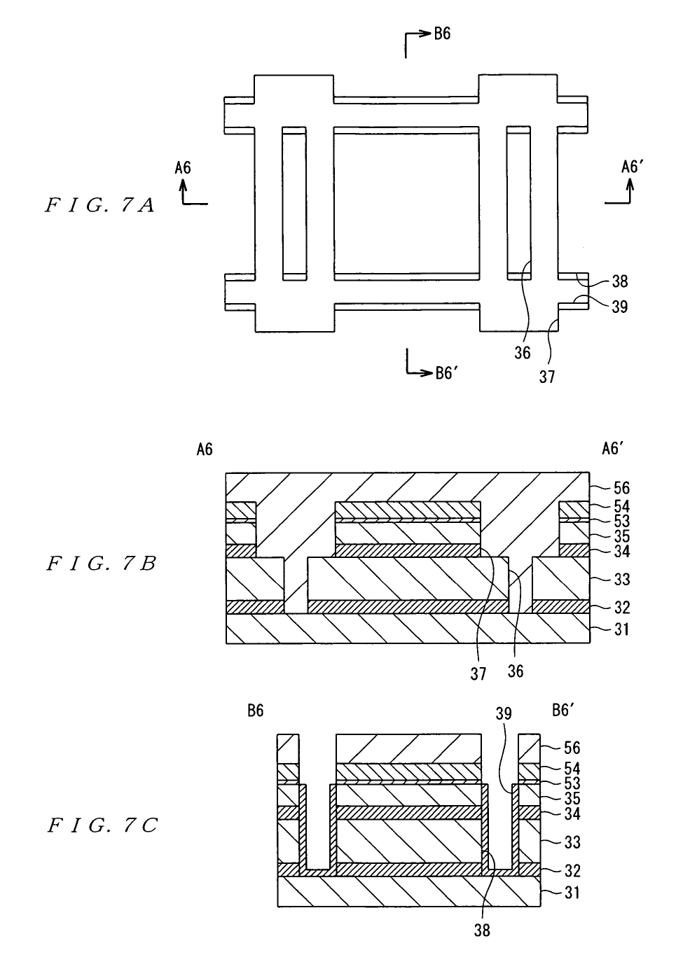

As shown in FIGS. 7A to 7C, the single-crystal semiconductor substrate 31 and single-crystal semiconductor layers 33 and 35 are thermally oxidized, thereby forming buried oxide films 32 in the cavities 57a between the single-crystal semiconductor substrate 31 and the single-crystal semiconductor layer 33 and forming buried oxide films 34 in the cavities 57b between the single-crystal semiconductor layers 33 and 35. To form the buried oxide films 32 and 34 by thermally oxidizing the single-crystal semiconductor substrate 31 and single-crystal semiconductor layers 33 and 35, low temperature wet oxidation, which provides reaction limited, is preferably used to improve the ease of filling. When the buried oxide films 32 and 34 are formed by thermally oxidizing the single-crystal semiconductor substrate 31 and single-crystal semiconductor layers 33 and 35, the single-crystal semiconductor substrate 31 and single-crystal semiconductor layers 33 and 35 in the trenches 38 are oxidized to form oxide films 39 on side walls in the trenches 38.

The film thicknesses of the single-crystal semiconductor layers 33 and 35 after element isolation can be defined by the film thicknesses of the single-crystal semiconductor layers 33 and 35 at the time of epitaxial growth and the film thicknesses of the buried oxide films 32 and 34 formed by thermally oxidizing the single-crystal semiconductor layers 33 and 35. Accordingly, it becomes possible to control the film thicknesses of the single-crystal semiconductor layers 33 and 35 with high precision and thus thin the single-crystal semiconductor layers 33 and 35 while decreasing variation in the film thickness of each of the single-crystal semiconductor layers 33 and 35. The provision of the oxidation-resistant film 54 on the single-crystal semiconductor layer 35 makes it possible to form the buried oxide films 34 on the back side of the single-crystal semiconductor layer 35 while preventing the surface of the single-crystal semiconductor layer 35 from being thermally oxidized.

The film thickness of the single-crystal semiconductor layer 33 larger than that of the single-crystal semiconductor layer 35 makes it possible to stably support the single-crystal semiconductor layers 33 and 35 on the single-crystal semiconductor substrate 31 even if the cavities 57a and 57b are formed under the single-crystal semiconductor layers 33 and 35, respectively. Thus, the film thicknesses of the single-crystal semiconductor layers 33 and 35 and buried oxide films 32 and 34 can be made uniform.

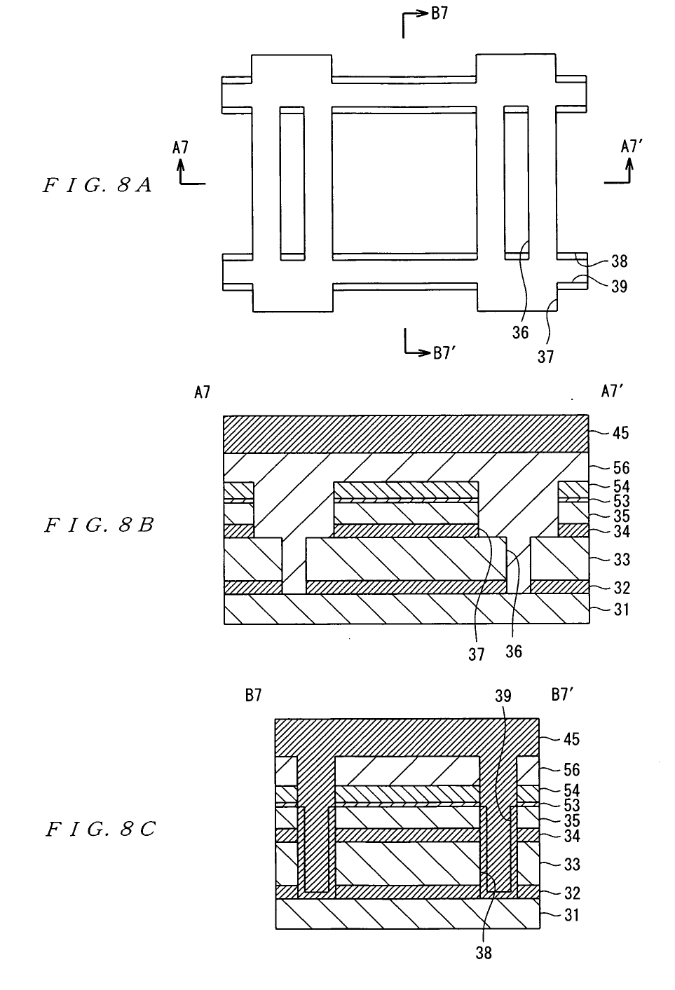

As shown in FIGS. 8A to 8C, a buried insulator 45 is deposited on the support 56 by CVD or the like such that the trenches 38 are filled in. Note that a silicon oxide film can be used as a material for the buried insulator 45.

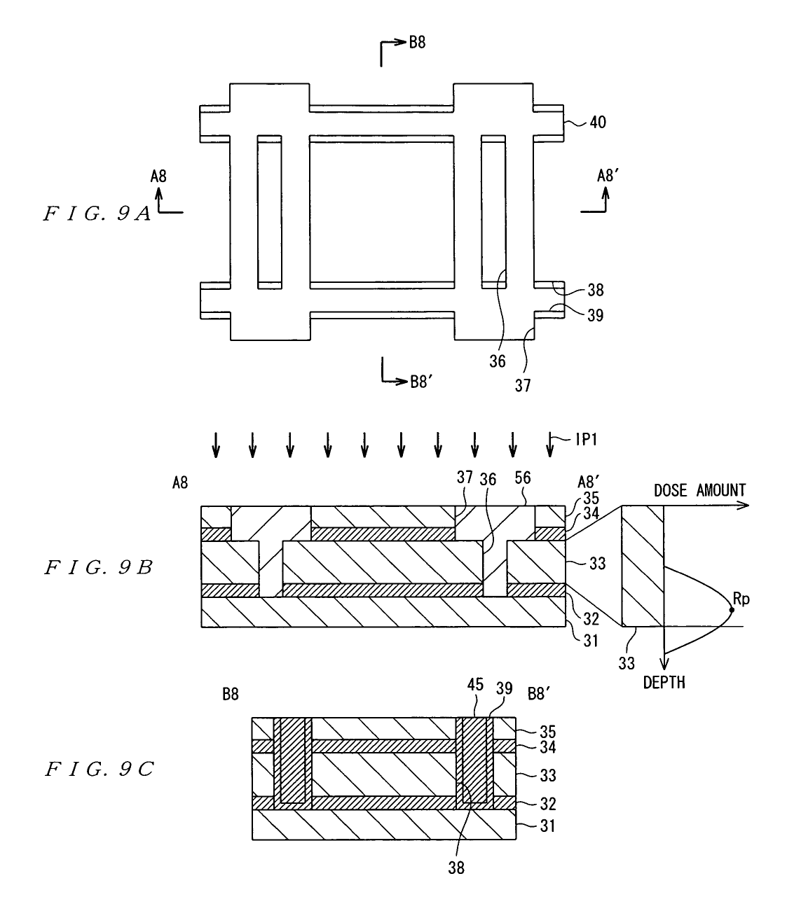

As shown in FIGS. 9A to 9C, the buried insulator 45 and support 56 are thinned by means of CMP (Chemical Mechanical Polishing) or the like, and the oxidation-resistant film 54 and sacrificial oxide film 53 are removed, thereby exposing the surface of the single-crystal semiconductor layer 35. An impurity is introduced into the single-crystal semiconductor layer.33 by the ion implant IP1 of impurities such as As, P, B, or BF₂ into the single-crystal semiconductor layer 33. A-range Rp of the impurity ion-implanted in the single-crystal semiconductor layer 33 is preferably set to be longer than the depth of the center in a direction of film thickness of the single-crystal semiconductor layer 33.

This configuration makes it possible to ensure a decrease in the resistance of the single-crystal semiconductor layer 33, which is to function as back gate electrodes, while suppressing damage to the single-crystal semiconductor layer 35, in which SOI transistors are to be formed and control the threshold value of each SOI transistor at a low voltage without deteriorating the characteristics of the SOI transistor.

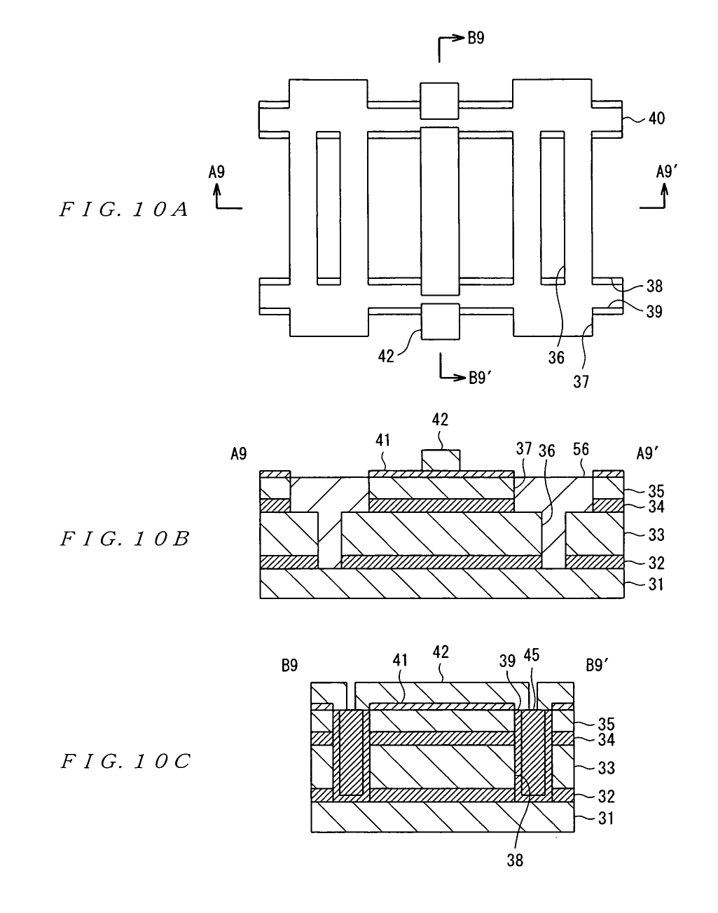

As shown in FIGS. 10A to 1C, gate insulating films 41 are formed on the surface of the single-crystal semiconductor layer 35 by thermally oxidizing the surface of the single-crystal semiconductor layer 35. A polysilicon layer is formed by CVD or the like on the single-crystal semiconductor layer 35, on which the gate insulating films 41 are formed. The polysilicon layer is patterned using a photolithography technique and etching technique, thereby forming gate electrodes 42 on the single-crystal semiconductor layer 35.

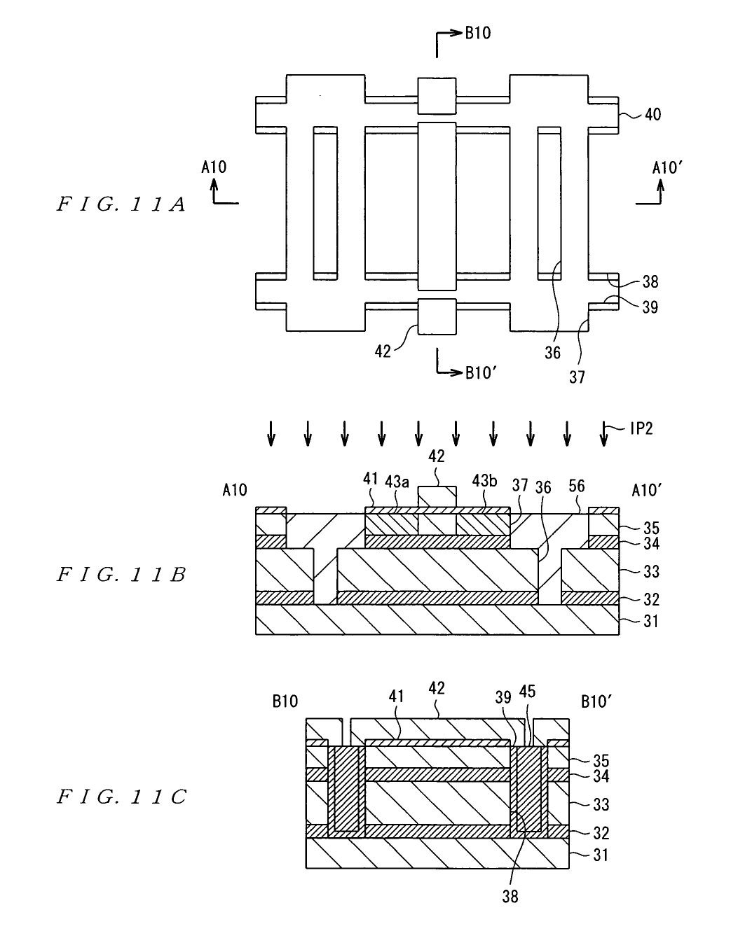

As shown in FIGS. 11A to 11C, the ion implant IP2 of impurities such as As, P, B, or BF₂ are performed into the single-crystal semiconductor layer 35 using the gate electrodes 42 as a mask, thereby forming, on the single-crystal semiconductor layer 35, source layers 43a and drain layers 43b which are arranged such that each gate electrode 42 is sandwiched between the corresponding source layer 43a and drain layer 43b.

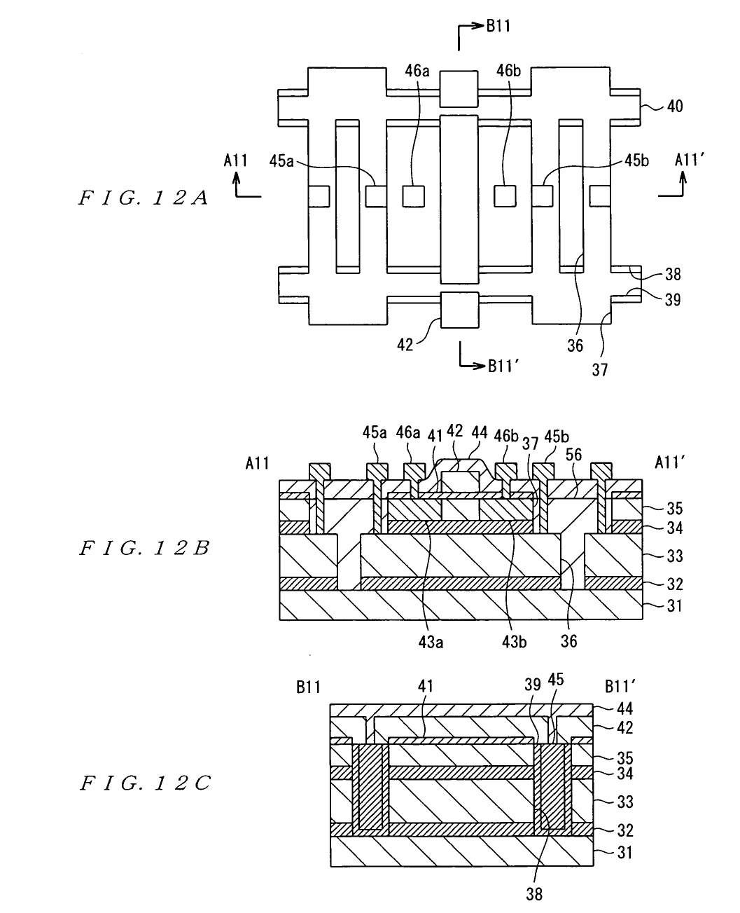

As shown in FIGS. 12A to 12C, an interlayer dielectric 44 is deposited on the gate electrodes 42 by CVD or the like. Back gate contact electrodes 45a and 45b which are buried in the interlayer dielectric 44 and support 56 and connected to the single-crystal semiconductor layer 33 are formed on the interlayer dielectric 44. Source contact electrodes 46a and drain contact electrodes 46b which are buried in the interlayer dielectric 44 and connected to the source layers 43a and drain layers 43b, respectively, are also formed on the interlayer dielectric 44.

This configuration makes it possible to arrange the single-crystal semiconductor layers 33 and 35 on the buried oxide films 32 and 34 while decreasing the occurrence of defects in the single-crystal semiconductor layers 33 and 35. It becomes possible to arrange back gate electrodes with decreased resistance on the back side of the single-crystal semiconductor layer 35 without using an SOI substrate and form SOI transistors in the single-crystal semiconductor layer 33. As a result, it becomes possible to decrease an off-leak current of each SOI transistor while suppressing an increase in cost and ensure an increase in the breakdown voltage of the SOI transistor.

Note that the gate electrodes 42 and single-crystal semiconductor layer 35 may be electrically connected to each other through the back gate contact electrodes 45a and 45b. This configuration makes it possible to control the back gate electrodes and gate electrodes 42 such that they are at the same potential and increase control over the potential of a channel region. Accordingly, an off-leak current can be decreased while suppressing an increase in chip size. This makes it possible to decrease power consumed during operation or standby and ensure an increase in the breakdown voltage of a field-effect transistor.

What is claimed is:

1. A semiconductor device comprising:
a back gate electrode composed of a first single-crystal semiconductor layer formed on a first insulating layer;
a second insulating layer formed on the first single-crystal semiconductor layer;
a second single-crystal semiconductor layer formed on the second insulating layer and having a film thickness smaller than a film thickness of the first single-crystal semiconductor layer;
a gate electrode formed on the second single-crystal semiconductor layer; and
source and drain layers that are formed on the second single-crystal semiconductor layer and arranged on respective sides of the gate electrode.

2. The semiconductor device according to claim 1, further comprising a wiring layer that electrically connects the back gate electrode and gate electrode.

3. A semiconductor device manufacturing method comprising:
a step of forming a first single-crystal semiconductor layer on a single-crystal semiconductor substrate;
a step of forming a second single-crystal semiconductor layer whose etching rate is lower than an etching rate of the first single-crystal semiconductor layer on the first single-crystal semiconductor layer;
a step of forming a third single-crystal semiconductor layer having the same composition as composition of the first single-crystal semiconductor layer on the second single-crystal semiconductor layer;
a step of forming a fourth single-crystal semiconductor layer having the same composition as composition of the second single-crystal semiconductor layer and a film thickness smaller than a film thickness of the second single-crystal semiconductor layer on the third single-crystal semiconductor layer;
a step of forming a first trench extending through the first to fourth single-crystal semiconductor layers to expose the single-crystal semiconductor substrate;
a step of forming, in the first trench, a support supporting the second and fourth single-crystal semiconductor layers on the single-crystal semiconductor substrate;
a step of forming a second trench that exposes at least part of the first and third single-crystal semiconductor layers from the second and fourth single-crystal semiconductor layers supported by the support formed in the first trench;
a step of selectively etching the first and third single-crystal semiconductor layers through the second trench to form first and second cavity portions obtained by removing the first and third single-crystal semiconductor layers;
a step of thermally oxidizing the semiconductor substrate and the second and fourth single-crystal semiconductor layers to form respective buried oxide films that fill in the first and second cavity portions;
a step of thermally oxidizing the fourth single-crystal semiconductor layer to form a gate insulating film on the fourth single-crystal semiconductor layer;
a step of forming a gate electrode on the fourth single-crystal semiconductor layer through the gate insulating film; and
a step of performing ion implantation using the gate electrode as a mask to form source and drain layers arranged on respective sides of the gate electrode on the fourth single-crystal semiconductor layer.

4. The semiconductor device manufacturing method according to claim 3, wherein the single-crystal semiconductor substrate and the second and fourth single-crystal semiconductor layers are made of Si, and the first and third single-crystal semiconductor layers are made of SiGe.

5. The semiconductor device manufacturing method according to claim 3, further comprising a step of ion-implanting, into the second single-crystal semiconductor layer, an impurity whose range is set to be longer than a depth of a center in a direction of film thickness of the second single-crystal semiconductor layer.
